(19) United States
(12) Patent Application Publication
(10) Pub. No.: US 2026/0075891 A1
(43) Pub. Date: Mar. 12, 2026

(54) HETEROJUNCTION BIPOLAR TRANSISTOR, RADIO FREQUENCY MODULE, AND COMMUNICATION DEVICE

(71) Applicant: XIAMEN SAN'AN INTEGRATED CIRCUIT CO., LTD., Xiamen (CN)

(72) Inventors: QI DING, Xiamen (CN); Xiangyang HE, Xiamen (CN); Wenbi CAI, Xiamen (CN); Houngchi WEI, Xiamen (CN); ChiaChu KUO, Xiamen (CN)

(21) Appl. No.: 19/322,705

(22) Filed: Sep. 9, 2025

(30) Foreign Application Priority Data
Sep. 10, 2024 (CN) 2024112666055
Apr. 24, 2025 (CN) 2025105208432
Apr. 24, 2025 (CN) 2025105208470

(51) Int. Cl. H10D 62/10; H10D 10/80; H10D 62/13; H10D 64/23; H10D 64/27

(52) U.S. Cl. CPC H10D 62/115; H10D 10/821; H10D 62/117; H10D 62/136; H10D 64/231; H10D 64/281

(57) ABSTRACT

Provided are a heterojunction bipolar transistor (HBT), a radio frequency module, and a communication device. The HBT includes: a semiconductor stack, an emitter metal, a first passivation layer, a first metal, and a dielectric layer. The semiconductor stack has first surface and second surfaces, and includes an emitter step and a base step having a step side surface. The emitter metal is disposed on the emitter step. The first passivation layer covers at least a side surface of the emitter metal and extends to cover a portion of the first surface exposed outside the emitter step, the step side surface, and a portion of the first surface exposed outside the base step. The first metal includes a base metal, which is at least partially disposed on the first surface, and is adjacent to the emitter step and spaced apart from the emitter step.

### TECHNICAL FIELD

The present disclosure relates to the field of semiconductor technologies, and particularly to a heterojunction bipolar transistor (HBT), a radio frequency (RF) module, and a communication device.

### BACKGROUND

As operating frequencies of RF amplifiers continue to increase, parasitic capacitance in HBT products has an increasingly significant impact on performance thereof. In existing HBT processes, when an M1 metal connects to an emitter metal, the M1 metal crosses over base metal, resulting in substantial parasitic capacitance between the M1 metal and the base metal.

### SUMMARY

An objective of the present disclosure includes, for example, providing an HBT. For the HBT, by arranging a dielectric layer parallel to a base step, a spacing between a metal and a semiconductor material may be increased, thereby achieving the effect of reducing parasitic capacitance

Embodiments of the present disclosure may be implemented as follows.

In a first aspect, an embodiment of the present disclosure provides an HBT, which includes: a semiconductor stack having a first surface and a second surface, the semiconductor stack includes an emitter step protruding from the first surface and a base step disposed on the second surface, the first surface is a surface of the base step facing away from the second surface, and the base step includes a step side surface connecting the first surface and the second surface; an emitter metal, disposed on the emitter step; a first passivation layer covering at least a side surface of the emitter metal and extending to cover a portion of the first surface exposed outside the emitter step, the step side surface, and a portion of the first surface exposed outside the base step; a first metal, including a base metal, the base metal is at least partially disposed on the first surface, and the base metal is adjacent to the emitter step and is spaced apart from the emitter step; and a dielectric layer, disposed on the second surface and arranged side by side with the base step, the dielectric layer is disposed on an outer side of the first passivation layer facing away from the semiconductor stack.

In a second aspect, an embodiment of the present disclosure provides an RF module, which includes the HBT described above.

In a third aspect, an embodiment of the present disclosure provides a communication device, which includes the RF module described above.

The embodiments of the present disclosure have at least the following beneficial effects.

By disposing the dielectric layer parallel to the base step, a spacing between a metal and a semiconductor material may be increased, thereby reducing parasitic capacitance. By providing a first isolation structure filled in a gap, a spacing between an emitter connection metal and a first finger portion may be increased, thereby reducing parasitic capacitance.

### BRIEF DESCRIPTION OF DRAWINGS

FIG. 1 illustrates a top view of a first basic structure of an HBT according to an embodiment of the present disclosure.

FIG. 2 illustrates a schematic sectional view along a line A-A of the first basic structure in FIG. 1.

FIG. 3 illustrates a schematic sectional view along a line B-B of the first basic structure in FIG. 1.

FIG. 4 illustrates a schematic structural view of the HBT according to the embodiment of the present disclosure, with a same perspective as FIG. 2.

FIG. 5 illustrates a schematic structural view of the HBT according to the embodiment of the present disclosure, with a same perspective as FIG. 3.

FIG. 6 illustrates a schematic structural view corresponding to a perspective of FIG. 2, showing a structure obtained after a step in a manufacturing method of the HBT according to an embodiment of the present disclosure.

FIG. 7 illustrates a schematic structural view corresponding to a perspective of FIG. 3, showing the structure of FIG. 6.

FIG. 8 illustrates a schematic structural view corresponding to the perspective of FIG. 2, showing a structure obtained after another step in a manufacturing method of the HBT according to an embodiment of the present disclosure.

FIG. 9 illustrates a schematic structural view corresponding to the perspective of FIG. 3, showing the structure of FIG. 8.

FIG. 10 illustrates a schematic structural view corresponding to the perspective of FIG. 2, showing a structure obtained after yet another step in a manufacturing method of the HBT according to an embodiment of the present disclosure.

FIG. 11 illustrates a schematic structural view corresponding to the perspective of FIG. 3, showing the structure of FIG. 10.

FIG. 12 illustrates a schematic structural view corresponding to the perspective of FIG. 2, showing a structure obtained after a further step in a manufacturing method of the HBT according to an embodiment of the present disclosure.

FIG. 13 illustrates a schematic structural view corresponding to the perspective of FIG. 3, showing the structure of FIG. 12.

FIG. 14 illustrates a schematic structural view of an HBT in the related art.

FIG. 15 illustrates a schematic structural view of the HBT shown in FIG. 14 from another perspective.

FIG. 16 illustrates a top view of another HBT according to an embodiment of the present disclosure.

FIG. 17 illustrates a schematic sectional view along a line C-C of the HBT shown in FIG. 16.

FIG. 18 illustrates a schematic sectional view along a line D-D of the HBT shown in FIG. 16.

FIG. 19 illustrates a schematic sectional view along a line C-C of yet another HBT according to an embodiment of the present disclosure.

FIG. 20 illustrates a schematic sectional view along a line D-D of the HBT shown in FIG. 19.

FIG. 21 illustrates a schematic sectional view along a line C-C of a further HBT according to an embodiment of the present disclosure.

FIG. 22 illustrates a schematic sectional view along a line C-C of still another HBT according to an embodiment of the present disclosure.

FIG. 23 illustrates a schematic sectional view along a line C-C of a structure obtained after a step in a manufacturing method of the HBT according to an embodiment of the present disclosure.

FIG. 24 illustrates a schematic sectional view along a line C-C of a structure obtained after a subsequent step following the step corresponding to FIG. 23.

FIG. 25 illustrates a schematic sectional view along a line D-D of a structure obtained after a subsequent step following the step corresponding to FIG. 24.

FIG. 26 illustrates a schematic sectional view along a line D-D of another HBT according to an embodiment of the present disclosure.

FIG. 27 illustrates a schematic sectional view along a line D-D of a modified embodiment of the another HBT in FIG. 26.

FIG. 28 illustrates a schematic sectional view along a line C-C of the HBT shown in FIG. 27.

### DETAILED DESCRIPTION OF EMBODIMENTS

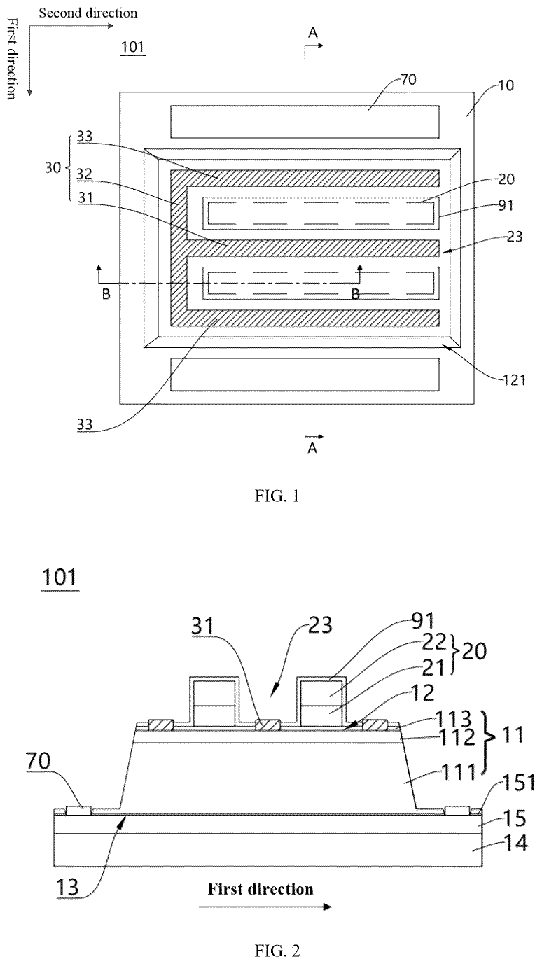

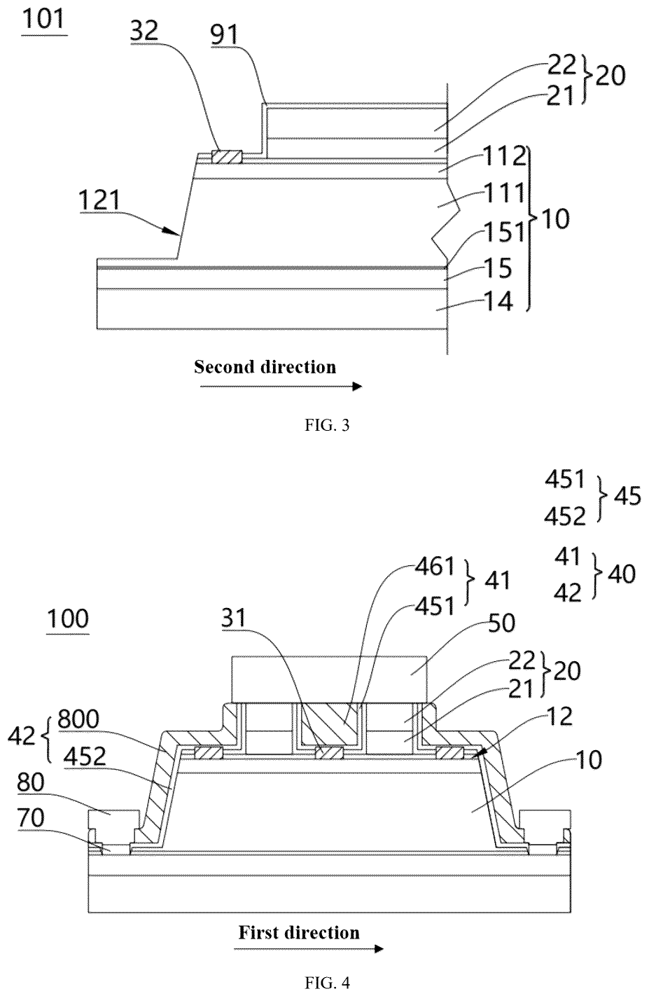

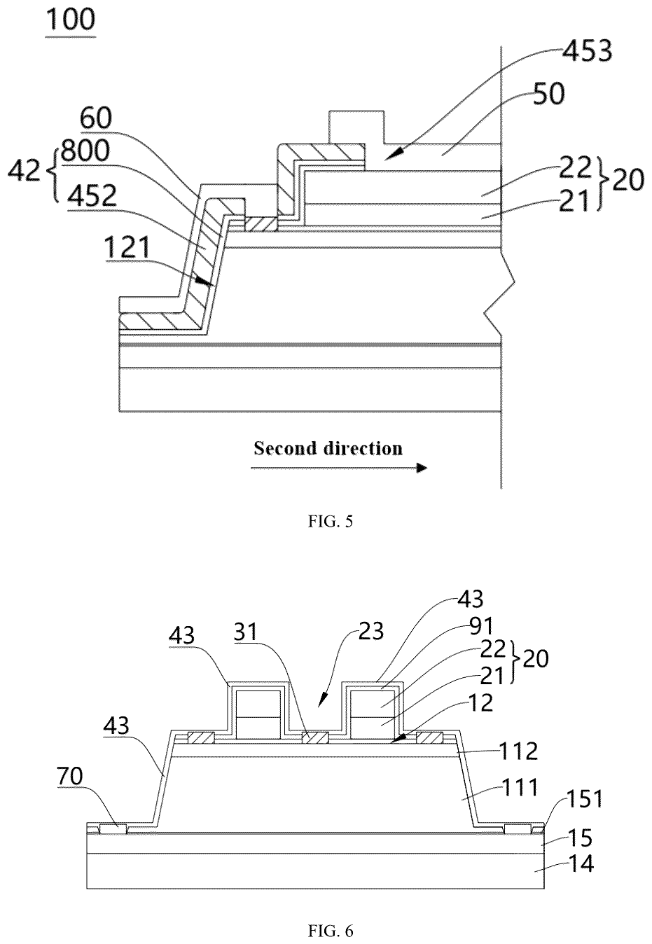

An embodiment of the present disclosure provides an HBT 100. To prevent certain structural layers from being obscured and difficult to illustrate due to mutual overlapping, FIGS. 1 to 3 first show a first basic structure 101 included in the HBT 100 provided by the embodiment. FIG. 1 illustrates a top view of the first basic structure 101 of the HBT 100. FIG. 2 illustrates a schematic sectional view along a line A-A of the first basic structure 101 in FIG. 1. FIG. 3 illustrates a schematic sectional view along a line B-B of the first basic structure 101 in FIG. 1. FIGS. 4, 6, 8, 10, and 12 are schematic structural views from a same perspective as FIG. 2. FIGS. 5, 7, 9, 11, and 13 are schematic structural views from a same perspective as FIG. 3.

Referring to FIGS. 1, 2, and 3, the first basic structure 101 includes a semiconductor stack 10, an emitter metal 22, and a first metal. Referring to FIG. 4, the HBT further includes a first passivation layer 45 and a dielectric layer 800. The semiconductor stack 10 has a first surface 12 and a second surface 13, and includes an emitter step 21 protruding from the first surface 12 and a base step 11 disposed on the second surface 13. The first surface 12 is a surface of the base step 11 facing away from the second surface 13. The base step 11 has a step side surface connecting the first surface 12 and the second surface 13. In this embodiment, the step side surface is a semiconductor slope 121. The emitter metal 22 is disposed on the emitter step 21. The first passivation layer 45 at least covers a side surface of the emitter metal 22, and extends to cover a portion of the first surface 12 exposed outside the emitter step 21, the step side surface, and a portion of the first surface 12 exposed outside the base step 11. The first metal includes a base metal 30, at least portion of the base metal 30 is disposed on the first surface 12, and the base metal 30 is adjacent to the emitter step 21 and is spaced apart from the emitter step 21. The dielectric layer 800 is disposed on the second surface 13 and is arranged side by side with the base step 11. The dielectric layer 800 is disposed on an outer side of the first passivation layer 45 facing away from the semiconductor stack 10.

In some embodiments, the first basic structure 101 further includes multiple emitter structures 20 and multiple collector metals 70. The multiple emitter structures 20 are disposed on the first surface 12, and are spaced apart from each other along a first direction, and a gap 23 is formed between every two adjacent emitter structures 20 of the multiple emitter structures 20. The base metal 30 includes first finger portions 31, each of the first finger portions 31 is provided in a corresponding one gap 23 and is in contact with and connected to the semiconductor stack 10.

In some embodiments, the semiconductor stack 10 specifically includes a substrate 14, a sub-collector 15, an etch stop layer 151, a collector 111, a base 112, and an emitter 113, which are sequentially stacked in that order. The base step 11 may include the collector 111, the base 112, and the emitter 113. A main material of the emitter 113 is InGaP, and the emitter 113 can act as an etch stop layer to protect the base 112 during an etching process. The first surface 12 is specifically a surface of the emitter 113 facing away from the base 112. A specific arrangement of the semiconductor stack 10 can refer to an arrangement of an epitaxial layer structure of a traditional HBT. The multiple collector metals 70 are connected to the sub-collector 15. In this embodiment, each emitter structure 20 includes an emitter step 21 (which may be referred to as EM) and an emitter metal 22 (which may be referred to as EC). The base metal 30 (which may be referred to as BC) includes multiple finger portions, finger portions located between every two adjacent emitter structures 20 are referred to as first finger portions 31, and finger portions (that is, located outside the multiple emitter structures 20) of the multiple finger portions other than the first finger portions 31 are referred to as second finger portions 33. A third passivation layer 91, which covers the first surface 12, is further disposed on the semiconductor stack 10. A surface of the base metal 30 facing away from the semiconductor stack 10 is exposed outside the third passivation layer 91. The third passivation layer 91 may be made of silicon nitride (SiN).

Referring to FIG. 4, the HBT 100 provided in this embodiment of the present disclosure further includes an isolation structure 40 and an emitter connection metal 50. The isolation structure 40 includes a first isolation structure 41, which fills the gap 23 and covers at least one first finger portion 31. The emitter connection metal 50 is disposed on sides of the multiple emitter structures 20 and the first isolation structure 41 facing away from the semiconductor stack 10, and the emitter connection metal 50 is in contact with and is connected to the multiple emitter structures 20. The isolation structure 40 is made of an insulating material, that is, the first isolation structure 41 is made of an insulating material, which may be an organic insulating material or an inorganic insulating material, or a combination of organic and inorganic insulating materials. The first isolation structure 41 can fill a portion of a depth of the gap 23, or an entire depth of the gap 23, which can also be understood as a height of a surface of the first isolation structure 41 facing away from the semiconductor stack 10 to the first surface 12 (i.e., the semiconductor stack 10) may be less than a height of a surface of the emitter structure 20 facing away from the semiconductor stack 10 to the first surface 12 (i.e., the semiconductor stack 10). Or, the height of the surface of the first isolation structure 41 facing away from the semiconductor stack 10 to the first surface 12 (i.e., the semiconductor stack 10) may be equal to the height of the surface of the emitter structure 20 facing away from the semiconductor stack 10 to the first surface 12 (i.e., the semiconductor stack 10). In some embodiments, when the first isolation structure 41 fills a portion of the depth of the gap 23, its filling depth is greater than or equal to 1150 angstroms.

FIG. 14 illustrates a schematic structural view of an HBT 100a in the related art, which includes a base pedestal 10a, emitter step layers 21a, and emitter contact metal layers 22a. One emitter step layer 21a and one emitter contact metal layer 22a form one set. A base metal layer finger portion 31a is disposed between two sets of emitter step layers 21a and emitter contact metal layers 22a, and a connection metal 50a connected to the emitter contact metal layer 22a is disposed between the two sets of emitter step layers 21a and emitter contact metal layers 22a. Referring to FIG. 14, a surface of the base metal layer finger portion 31a facing away from the base pedestal 10a is exposed from a first silicon nitride layer 91a, and a second silicon nitride layer 92a covers the base metal layer finger portion 31a. The connection metal 50a and the base metal layer finger portion 31a are only separated by one layer of the second silicon nitride layer 92a. A thickness of the second silicon nitride layer 92a is generally about 250 angstroms (Å, 1 Å angstrom=10⁻¹⁰ meters), and thus the second silicon nitride layer 92a is relatively thin. Therefore, a relatively large parasitic capacitance will be generated between the connection metal 50a and the base metal layer finger portion 31a. In this embodiment, by setting the first isolation structure 41 filled in the gap 23, a spacing between the emitter connection metal 50 and the first finger portion 31 may be increased, thereby reducing the parasitic capacitance. In this embodiment, a line width (i.e., the width along a direction in which the multiple emitter structures 20 are arranged) of the emitter connection metal 50 may be less than or equal to 2 micrometers.

In some embodiments, the first passivation layer 45 includes a first portion 451. The HBT 100 further includes a first dielectric layer 461. The first portion 451 of the first passivation layer 45 covers a surface of the first finger portion 31 facing away from the semiconductor stack 10 and covers side surfaces of two adjacent emitter structures 20 facing towards the gap 23. The first dielectric layer 461 is disposed on a side of the first portion 451 facing away from the semiconductor stack 10. Materials of the first portion 451 of the first passivation layer 45 and the first dielectric layer 461 are different. The first portion 451 of the first passivation layer 45 and the first dielectric layer 461 together form the first isolation structure 41. For example, the first portion 451 of the first passivation layer 45 may be an inorganic insulating material, and the first dielectric layer 461 may be an organic insulating material. For example, the first portion 451 of the first passivation layer 45 may be made of silicon nitride material, and the first dielectric layer 461 may be formed by polybenzoxazole (PBO) or polyimide (PI). In some embodiments, the first dielectric layer 461 may be formed by a photosensitive dielectric material, which may be PBO.

In some embodiments, when the first portion 451 of the first passivation layer 45 is made of silicon nitride material, it may be formed by a deposition process, and may be prepared using existing steps in a manufacturing process of a traditional HBT device. When the first dielectric layer 461 is made of an organic insulating material, the organic insulating material may be formed by coating and curing processes, which can achieve better filling effects. Moreover, when the first dielectric layer 461 is made of the organic insulating material, a dielectric constant of the first dielectric layer 461 is smaller than that of the silicon nitride material, which is more conducive to reducing parasitic capacitance. That is, in some embodiments, the dielectric constant of the first dielectric layer 461 is less than that of the first portion 451 of the first passivation layer 45. In some embodiments, a thickness range of the first portion 451 of the first passivation layer 45 is 150 angstroms to 1000 angstroms, which may be specifically 250 angstroms. This thickness range of the first portion 451 of the first passivation layer 45 can increase a protection function of the first passivation layer 45 on the first finger portion 31. In some embodiments, a thickness of the first dielectric layer 461 is greater than or equal to 1000 angstroms, which can specifically be 3000 to 10000 angstroms.

Of course, in some embodiments, the first isolation structure 41 may also be formed of a single material. For example, in some embodiments, the first isolation structure 41 is formed of a silicon nitride material.

In some embodiments, a thickness of the emitter metal 22 may be increased to make the first isolation structure 41 filled in the gap 23 thicker, which can further reduce parasitic capacitance. Specifically, a spacing between a surface of the emitter metal 22 facing away from the semiconductor stack 10 and a surface of the base metal 30 facing away from the semiconductor stack 10 is greater than or equal to 3000 angstroms. In other words, a height of the emitter metal 22 protruding the base metal 30 is 3000 angstroms or more.

In some embodiments, as shown in FIGS. 1 and 3, the semiconductor stack 10 further has a semiconductor slope 121 adjacent to the first surface 12. The base metal 30 further includes a first connection portion 32 disposed on the first surface 12, and the first connection portion 32 is connected to the first finger portion 31. Referring to FIG. 5, the first passivation layer 45 further includes a second portion 452, which covers the semiconductor slope 121. The isolation structure 40 further includes a second isolation structure 42. The dielectric layer 800 and the second portion 452 of the first passivation layer 45 together form the second isolation structure 42. The HBT 100 further includes a base connection metal 60, and the base connection metal 60 is connected to the base metal 30 and extends onto a side of the dielectric layer 800 facing away from the second portion 452 of the first passivation layer 45.

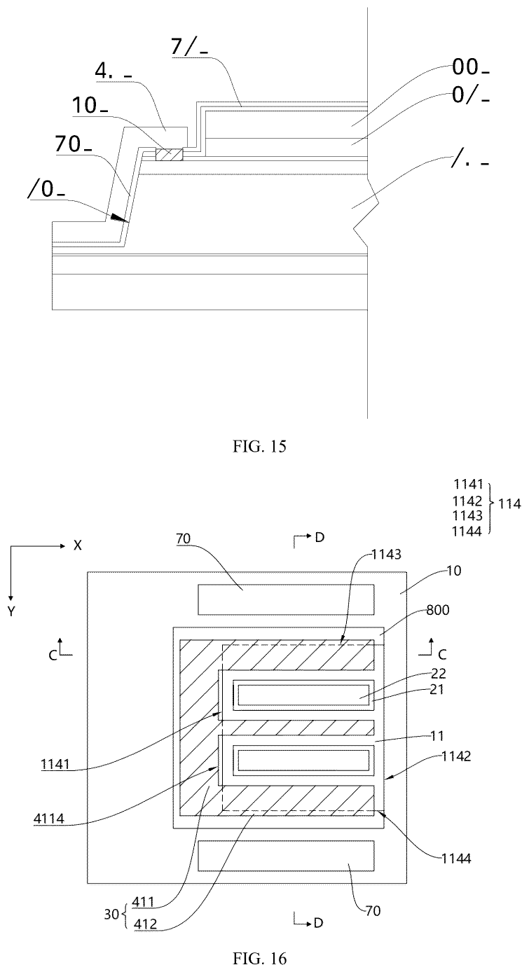

In the related art, as shown in FIG. 15, FIG. 15 illustrates a schematic structural view of the HBT shown in FIG. 14 from another perspective, a base connection metal 60a is connected to a base metal layer end 32a through an opening in the second silicon nitride layer 92a and is disposed along a base slope 12a. In this case, the base connection metal 60a and the base slope 12a are separated only by the second silicon nitride layer 92a, which will also produce a relatively large parasitic capacitance. In this embodiment of the present disclosure, the dielectric layer 800 is disposed between the base connection metal 60 and the semiconductor slope 121, which can increase a spacing between the semiconductor slope 121 and the base connection metal 60 and reduce the parasitic capacitance between the base connection metal 60 and the collector 111.

In some embodiments, a thickness of the dielectric layer 800 is greater than or equal to 5000 angstroms.

In some embodiments, the first portion 451 and the second portion 452 of the first passivation layer 45 may be formed simultaneously, that is, the first portion 451 and the second portion 452 of the first passivation layer 45 may be different parts of a same passivation layer material. In some embodiments, the first dielectric layer 461 and the dielectric layer 800 may be formed simultaneously, that is, the first dielectric layer 461 and the dielectric layer 800 may be different parts of a same dielectric layer material.

In some embodiments, the first passivation layer 45 covers the semiconductor stack 10 and the multiple emitter structures 20, and the first passivation layer 45 defines contact openings 453 (as shown in FIG. 5). The multiple emitter structures 20 are disposed with intervals in the first direction, and surfaces of the multiple emitter structures 20 facing away from the semiconductor stack 10 are connected to the emitter connection metal 50 through the contact openings 453. A spacing between outermost opposing edges of the multiple emitter structures 20 in the first direction is less than a width of each contact opening 453 in the first direction. Referring to FIG. 4, two emitter structures 20 are disposed spaced apart in the first direction, the first passivation layer 45 further covers sidewalls of the two emitter structures 20, the spacing between the outermost opposing edges of multiple emitter structures 20 in the first direction is a spacing between a left edge of a left emitter structure 20 and a right edge of a right emitter structure 20 in FIG. 4, and this spacing is less than the width of the contact opening 453 in the first direction. Therefore, from the perspective of FIG. 4, top surfaces of the multiple emitter structures 20 are completely exposed outside the passivation layer 45, ensuring an effective line width for the connection between the emitter connection metal 50 and the multiple emitter structures 20.

Referring to FIGS. 6 to 13, an embodiment of the present disclosure also provides a manufacturing method of the HBT 100, which includes the following steps S1-S3.

In step S1, a first basic structure 101 is provided. The first basic structure 101 includes: a semiconductor stack 10; multiple emitter structures 20, which are disposed on the first surface 12 with intervals therebetween, and a gap 23 is formed between every two adjacent emitter structures 20 of the multiple emitter structures 20; and a base metal 30, which includes first finger portions 31, each of the first finger portions 31 is provided in a corresponding one gap 23 and is in contact with and connected to the semiconductor stack 10.

In step S2, an isolation structure 40 is prepared. The isolation structure 40 includes a first isolation structure 41. Specifically, step S2 includes forming the first isolation structure 41 in the gaps 23, and making the first isolation structure 41 fill the gaps 23 and cover the first finger portions 31. The isolation structure 40 is made of an insulating material.

In step S3, an emitter connection metal 50 is disposed on a side of the multiple emitter structures 20 and the first isolation structure 41 facing away from the semiconductor stack 10, to make the emitter connection metal 50 be in contact with and is connected to the multiple emitter structures 20.

The specific configuration of the first base structure 101 in step S1 may refer to those shown in FIGS. 1 to 3. The preparation of the isolation structure 40 in step S2 can be designed and selected based on a material of the first isolation structure 41. For example, in some embodiments, step S2 specifically includes steps S21 and S22. In step S21, a first portion 451 of a first passivation layer, such that the first portion 451 of the first passivation layer covers a surface of the first finger portion 31 facing away from the semiconductor stack 10 and covers side surfaces of two adjacent emitter structures 20 facing towards the gap 23. In step S22, a first dielectric layer 461 is disposed on the first portion 451 of the first passivation layer. A material of the first portion 451 of the first passivation layer is different from that of the first dielectric layer 461. The first portion 451 of the first passivation layer and the first dielectric layer 461 together constitute the first isolation structure 41.

For example, the first portion 451 of the first passivation layer may be made of an inorganic insulating material, specifically silicon nitride material, and the first portion 451 may be formed by deposition. Therefore, the first portion 451 can cover the surface of the first finger portion 31 and the side surfaces of the multiple emitter structures 20, to ensure multi-directional coverage and insulation. The first portion 451 protects the first finger portion 31 and the semiconductor material exposed beyond the first finger portion 31, thereby preventing the first dielectric layer 461 from directly contacting the semiconductor material, which could compromise device reliability. The first dielectric layer 461 may be made of an organic insulating material and may be formed by coating and curing, which is convenient for filling the gaps 23. The first dielectric layer 461 can specifically be made of a photosensitive dielectric material.

Of course, in some other embodiments, a single material can also be used to form the first isolation structure 41 in step S2, for example, only silicon nitride material may be used to form the first isolation structure 41. At this time, the first isolation structure 41 may be formed by a single deposition or multiple depositions.

In some embodiments, the semiconductor stack 10 has a first surface 12 and a semiconductor slope 121 adjacent to the first surface 12. The base metal 30 also includes a first connection portion 32 disposed on the first surface 12, which is connected to the first finger portion 31. The isolation structure 40 also includes a second isolation structure 42. In some embodiments, preparation steps of the isolation structure 40 in step S2 specifically includes steps S23 through S26.

In step S23, a passivation layer material 43 is deposited on the semiconductor stack 10, to make the passivation layer material 43 cover the semiconductor stack 10, the base metal 30, and the multiple emitter structures 20.

In step S24, photolithography is performed on the passivation layer material 43 to form the first passivation layer 45. The first passivation layer 45 includes the first portion 451 of the first passivation layer disposed in the gaps 23 and the second portion 452 of the first passivation layer disposed on the semiconductor slope 121.

In step S25, a dielectric layer material 44 is coated on the passivation layer material 43, to make the dielectric layer material 44 cover the passivation layer 45 and fill the gaps 23.

In step S26, photolithography and curing are performed on the dielectric layer material 44 to form a first dielectric layer 461 and a dielectric layer 800. The first dielectric layer 461 fills the gaps 23, and the dielectric layer 800 covers the second portion 452 of the first passivation layer. The first dielectric layer 461 and the first portion 451 of the first passivation layer together form the first isolation structure 41, and the dielectric layer 800 and the second portion 452 of the first passivation layer together form the second isolation structure 42.

After step S2, the manufacturing method may further include step S4: forming a base connection metal 60 on the dielectric layer 800, and connecting the base connection metal 60 to the first connection portion 32 of the base metal 30.

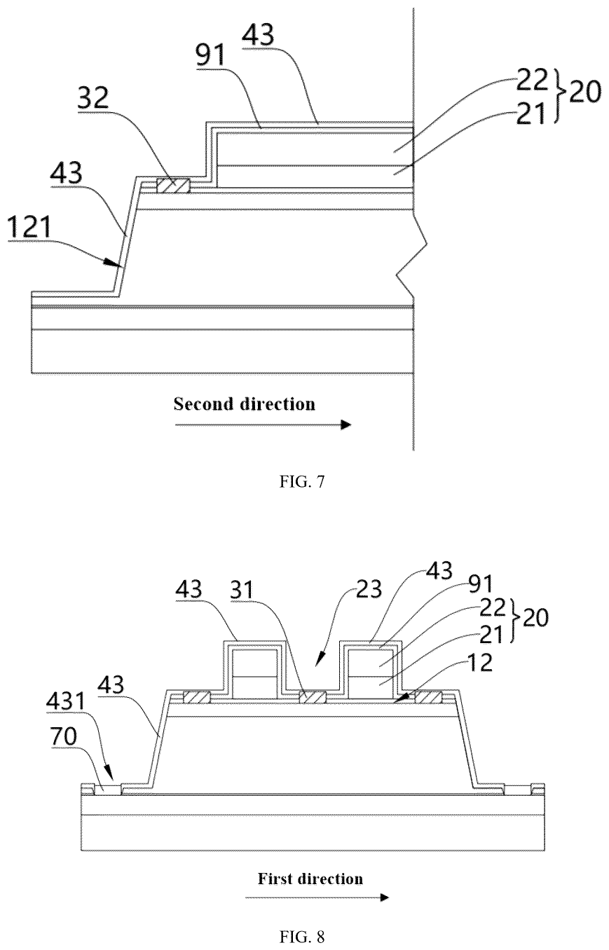

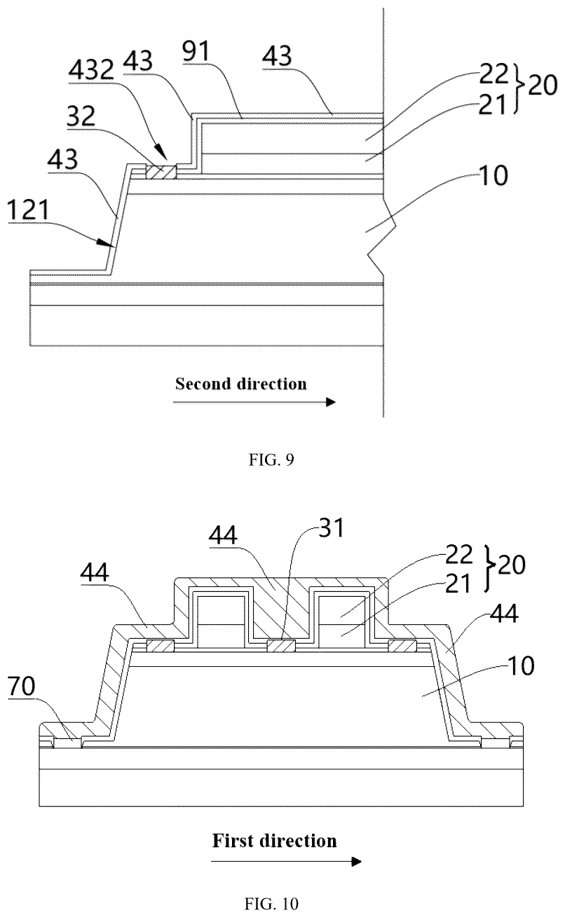

A structure obtained after step S23 is shown in FIGS. 6 and 7, a structure obtained after step S24 is shown in FIGS. 8 and 9, and a structure obtained after step S25 is shown in FIGS. 10 and 11. The passivation layer material 43 in step S23 is, for example, a silicon nitride material. In step S24, a layer of photoresist material is first applied on the passivation layer material 43, the layer of photoresist material is exposed and developed by using a photomask with a specific pattern, and then the layer of photoresist material is photoetched, a portion of the passivation layer material 43 exposed outside the layer of photoresist material is removed, forming a first opening 431 in FIG. 8 to expose the collector metal 70 outside the passivation layer material 43, and forming a second opening 432 in FIG. 9 to expose the first connection portion 32 of the base metal 30 outside the passivation layer material 43. In this embodiment, according to the different regions on the semiconductor stack 10, a portion of the first passivation layer within the gaps 23 is referred to as the first portion 451 of the first passivation layer, and other portion of first passivation layer covering the semiconductor slope 121 is referred to as the second portion 452 of the first passivation layer. From a process perspective, the first portion 451 and the second portion 452 are actually two parts of a same passivation layer.

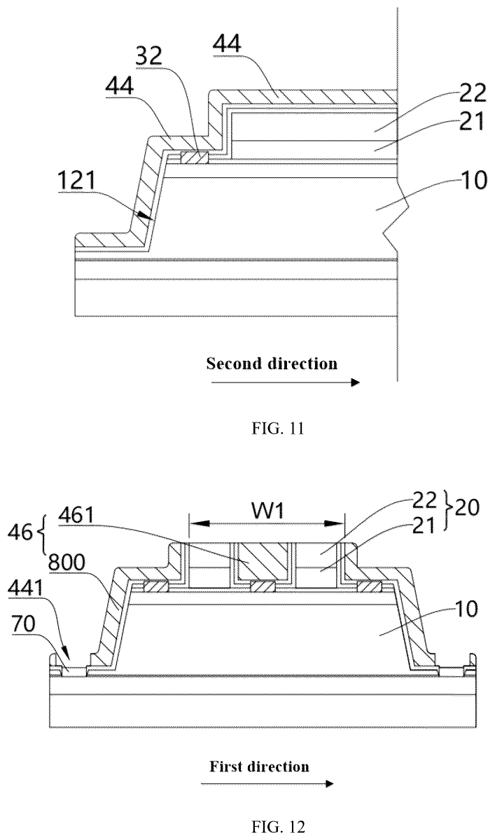

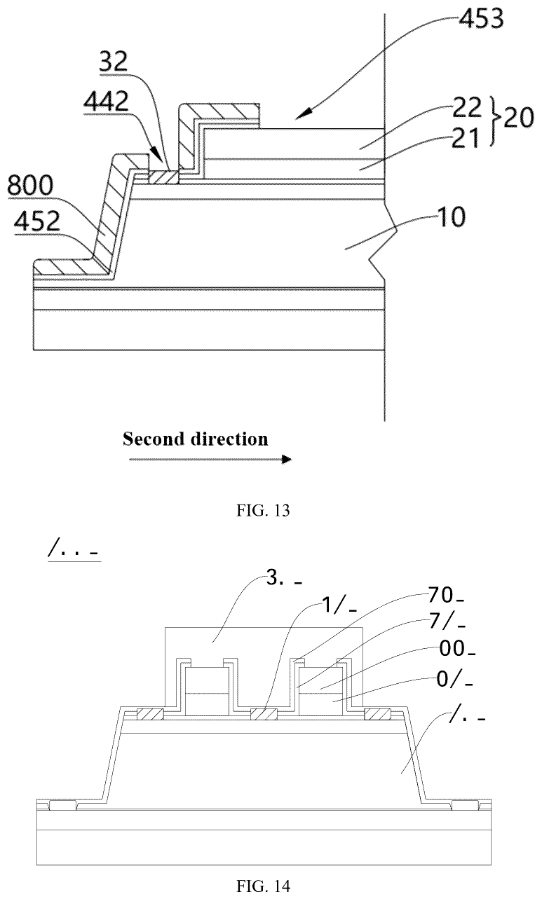

In step S25, the dielectric layer material 44 may be, for example, PBO or photosensitive PI and other photosensitive dielectric materials. The gaps 23 are filled by coating. In step S26, for example, a layer of photoresist material is specifically disposed on the dielectric layer material 44, the layer of photoresist material is exposed and developed by using a photomask with a specific pattern, and then the layer of photoresist material is photoetched, a portion of the dielectric layer material 44 exposed outside the layer of photoresist material is removed, forming a third opening 441 in FIG. 12 to expose the collector metal 70 outside the dielectric layer material 44, and forming a fourth opening 442 in FIG. 13 to expose the first connection portion 32 of the base metal 30 outside the dielectric layer material 44. The base connection metal 60 may be connected to the first connection portion 32 through the first opening 431 and the third opening 441. The collector connection metal 80 may be connected to the collector metal 70 through the second opening 432 and the fourth opening 442. In some embodiments, a width of the third opening 441 is greater than or equal to a width of the first opening 431, and a width of the fourth opening 442 is greater than or equal to a width of the second opening 432.

Through the above steps S23 to S26, the first portion 451 and the second portion 452 of the first passivation layer may be formed simultaneously, and the first dielectric layer 461 and the dielectric layer 800 may be formed simultaneously. As such, isolation structures are formed both in the gaps 23 and on the semiconductor slope 121, achieving the effect of reducing parasitic capacitance at multiple locations.

In some embodiments, when the dielectric layer material 44 is a photosensitive dielectric material and step S26 is followed by a step S27. In step S27, a first mask is used to perform back etching on the dielectric layer material 44 and the first passivation layer 45 to expose surfaces of the multiple emitter structures 20 facing away from the semiconductor stack 10 from the first passivation layer 45. The first mask has a first window, and a spacing between outermost opposing edges of multiple emitter structures 20 in the first direction is less than a width of the first window in the first direction. A structure obtained after step S27 is shown in FIGS. 12 and 13.

Specifically, the spacing between the outermost opposing edges of multiple emitter structures 20 in the first direction is referred to as W1 in FIG. 12. The width of the first window in the first direction is greater than W1, so that the dielectric layer (including the first dielectric layer 461 and the dielectric layer 800) and the first passivation layer 45 on a top of the multiple emitter structures 20 are within the first window. A single first window may be used to perform back etching on the dielectric layer and the first passivation layer 45 on the top of the multiple emitter structures 20. In step S27, since the dielectric layer material 44 itself is a photosensitive dielectric material, there is no need to dispose a photoresist layer and back etching may be performed directly, which can reduce process steps and lower process difficulty. However, this embodiment is not limited to this, and in some embodiments, a photosensitive medium can also be used to achieve a same structure in step S27 by controlling exposure and development methods.

In a coating process of the aforementioned step S25, due to the fluidity of the material, a thickness of a surface at a higher position will be thinner. For example, a thickness of the dielectric layer on the top of the multiple emitter structures 20 is thinner. Therefore, during the back etching in step S27, the passivation layer and the dielectric layer on the top of the multiple emitter structures 20 are etched first. When the passivation layer on top of the multiple emitter structures 20 is completely etched, exposing the top of the multiple emitter structures 20 from the passivation layer, the dielectric layer at other locations within the first window has not yet been completely etched and is thus preserved. After step S28, step S3 is performed, in which the emitter connection metal 50 formed in step S3 is separated from the first finger portion 31 by the first isolation structure 41, which can make the parasitic capacitance between the emitter connection metal 50 and the first finger portion 31 smaller.

In some embodiments, the emitter structures 20 in the first basic structure 101 provided in step S1 may be set to be higher so that more of the dielectric layer at other locations is retained when the emitter structures 20 are exposed from the passivation layer. Specifically, each emitter structure 20 of the multiple emitter structures 20 includes an emitter step 21 and an emitter metal 22 stacked in sequence on the first surface 12. A spacing between a surface of the emitter metal 22 facing away from the semiconductor stack 10 and a surface of the base metal 30 facing away from the semiconductor stack 10 is greater than or equal to 3000 angstroms, that is, a thickness of the emitter metal 22 is increased in step S1.

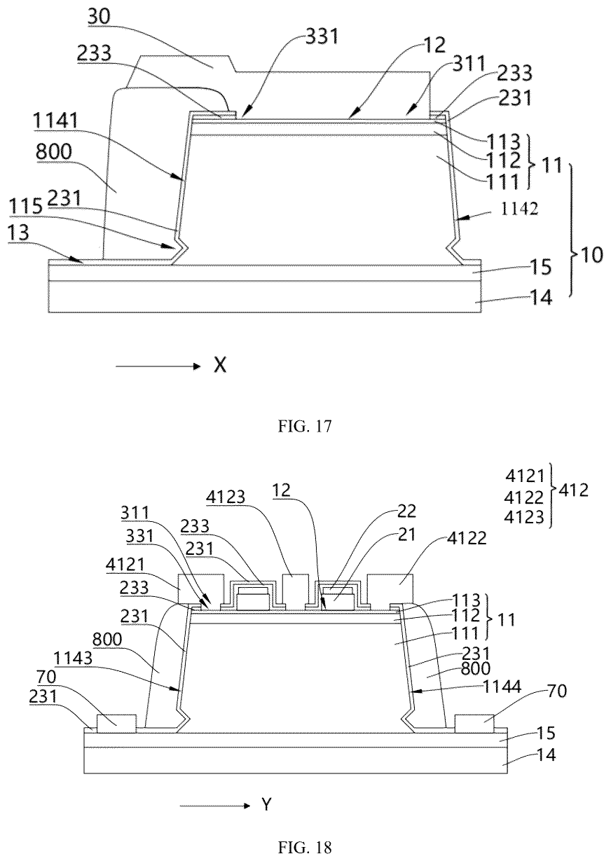

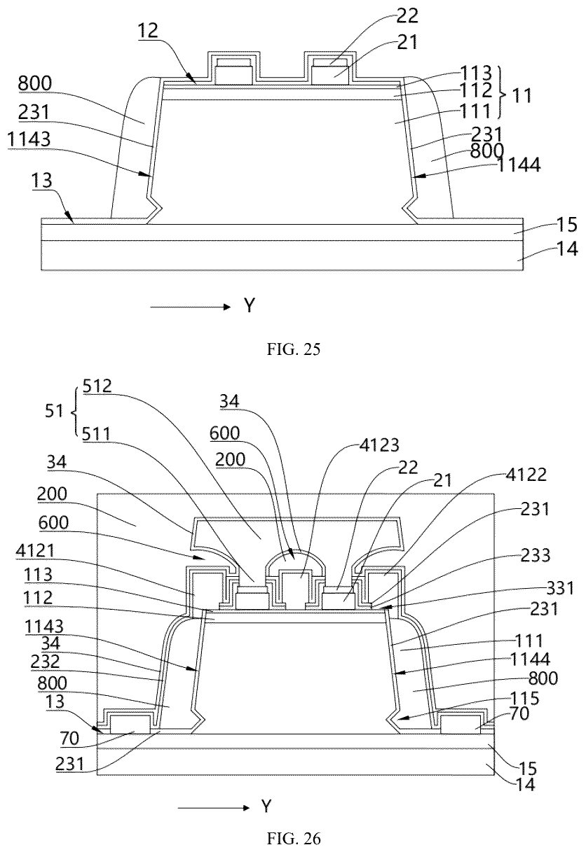

Another embodiment of the present disclosure also provides another HBT. To more clearly show a main structure of the HBT provided in this embodiment, FIG. 16 only shows a portion of a structure of the HBT, the first passivation layer 231 is made transparent for better visibility, and a pattern of the base metal 30 has been filled for better distinction of boundaries of each structure. Cross-sections shown in FIGS. 17, 19, 21, 23, and 24 correspond to a same position as a C-C cross-section in FIG. 16. Cross-sections shown in FIGS. 18, 20, 22, and 25 correspond to a same position as a D-D cross-section in FIG. 16. A Y direction is the first direction, and an X direction is the second direction.

Referring to FIG. 16, the HBT provided in this embodiment of the disclosure includes a semiconductor stack 10, an emitter metal 22, a first passivation layer 231, and a first metal 240. Referring to FIG. 17, the semiconductor stack 10 has a first surface 12 and a second surface 13. The semiconductor stack 10 includes an emitter step 21 protruding from the first surface 12 and a base step 11 located on the second surface 13, as shown in FIG. 18. The first surface 12 is a surface of the base step 11 facing away from the second surface 13. The base step 11 has a step side surface 114 connecting the first surface 12 and the second surface 13. The emitter metal 22 is disposed on the emitter step 21. The first passivation layer 231 at least covers a side surface of the emitter metal 22 and extends to cover a portion of the first surface 12 exposed outside the emitter step 21, the step side surface 114, and a portion of the first surface 12 exposed outside the base step 11. The first passivation layer 231 defines a fifth opening 311 disposed on the first surface 12. The first metal includes a base metal 30, and at least portion of the base metal 30 is located on the first surface 12, and is adjacent to the emitter step 21 and is spaced apart from the emitter step 21. The base metal 30 is connected to the semiconductor stack 10 through the fifth opening 311 and extends at least partially beyond an edge of the first surface 12.

Specifically, the semiconductor stack 10 includes a substrate 14 and a sub-collector 15 stacked in sequence. The base step 11 is located on the sub-collector 15, and a surface of the sub-collector 15 facing away from the substrate 14 is the second surface 13. In some embodiments, an etch stop layer may be further provided on the sub-collector 15, and the base step 11 is disposed on the etch stop layer, in this case, a surface of the etch stop layer facing away from the sub-collector 15 is the second surface 13. On the second surface 13, a collector 111, a base 112, and an emitter 113 are stacked in sequence to form the base step 11. The first surface 12 is a surface of the emitter 113 facing away from the base 112. Specifically, the base metal 30 is connected to the emitter 113 through the fifth opening 311 and then alloyed with the emitter 113 to connect to the base 112. Alternatively, an opening may be defined in the emitter 113, and the base metal 30 passes through the opening in the emitter 113 to connect to the base 112.

The base step 11 has multiple step side surfaces 114, including a third side surface 1143 and a fourth side surface 1144 facing towards each other in the first direction, a first side surface 1141 adjacent to the third side surface 1143 and the fourth side surface 1144, and a second side surface 1142 facing the first side surface 1141 in the second direction. The multiple step side surfaces 114 may be inclined relative to the second surface 13. Each of the multiple step side surfaces 114 may also have a recessed portion 115 located on the collector 111. At two sides of the base step 11 in the first direction, there are collector metals 70 connected to the sub-collector 15.

A material of the substrate 14 may be a III-V semiconductor, such as any one or a combination of GaN, AlGaN, AlN, GaAs, AlGaAs, InP, InGaAs, or InAlAs. The sub-collector 15 may be a III-V semiconductor, such as any one or a combination of GaN, AlGaN, AlN, GaAs, AlGaAs, InP, InGaAs, or InAlAs. The etch stop layer may be a III-V semiconductor, such as any one or a combination of InGaP, InGaAs, GaAsP, AlGaAs, InAlAs, or GaSb. The collector 111 may be a III-V semiconductor, such as any one or a combination of GaN, AlGaN, AlN, GaAs, AlGaAs, InP, InGaAs, or InAlAs. The base 112 may be a III-V semiconductor, such as any one or a combination of GaN, AlGaN, AlN, GaAs, AlGaAs, InP, InGaAs, or InAlAs. The emitter 113 may be a III-V semiconductor, such as any one or a combination of GaN, AlGaN, AlN, GaAs, AlGaAs, InP, InGaAs, InAlAs, or InGaP. The emitter 113 may be a multilayer structure. In an embodiment, a doping type of each of the sub-collector 15, the collector 111, and the emitter 113 is a first doping type, and a doping type of the base 112 is a second doping type. When the first doping type is n-type, the second doping type is p-type. When the first doping type is p-type, the second doping type is n-type.

The emitter step 21 may be a multilayer structure, for example, including an InGaAs layer and a GaAs layer. Specifically, the InGaAs layer serves as a cap layer for forming ohmic contact with the emitter metal 22, while the GaAs layer is used to address a lattice matching issue between InGaAs in the cap layer and InGaP in the emitter. The emitter metal 22 may include a conductive metal such as Ti, Pt, Au, Al, Cu, W, Ni, or Ge. As shown in FIGS. 16 and 18, a width of the emitter metal 22 may differ from that of the emitter step 21 Alternatively, in some embodiments, the width of the emitter metal 22 may be equal to that of the emitter step 21. Each of the emitter steps 21 and the emitter metal 22 may be at least two in number. Referring to FIGS. 18, 20, and 22, multiple emitter metals 22 may be interconnected via the second metal 51 and connected to an external circuitry. The second metal 51 may be a multilayer metal stack such as Ti/Pt/Au.

The first passivation layer 231 may be made of any one or a combination of insulating materials such as SiN, Si₃N₄, Si₂N₃, SiO₂, SiON, Al₂O₃, AlN, PI, benzocyclobutene (BCB), or PBO. A thickness of the first passivation layer 231 is, for example, 100 Å to 1000 Å. For instance, the first passivation layer 231 includes a first portion covering a top of the emitter metal 22, a second portion covering sidewalls of the emitter metal 22 and the emitter step 21, a third portion covering the first surface 12, a fourth portion covering the step side surface 114, and a fifth portion covering a portion of the second surface 13.

In some embodiments, a third passivation layer 233 is further disposed on an inner side of the first passivation layer 231. A material of the third passivation layer 233 may be configured with reference to the material of the first passivation layer 231. The third passivation layer 233 covers the top of the emitter metal 22, sidewalls of the emitter step 21 and the emitter metal 22, and a portion of the first surface 12 exposed outside the emitter step 21. The first passivation layer 231 covers the emitter step 21, the emitter metal 22, and the first surface 12 via the third passivation layer 233. A thickness of the third passivation layer 233 ranges from 100 Å to 1000 Å. A seventh opening 331 is defined on the third passivation layer 233 and connected to the fifth opening 311, thereby allowing the base metal 30 to connect to the semiconductor stack 10 through the fifth opening 311 and the seventh opening 331.

The base metal 30 may be a multilayer metal stack of Pt/Ti/Pt/Au/Ti. In some embodiments, a thickness of the base metal 30 is greater than a sum of thicknesses of the emitter step 21 and the emitter metal 22. Alternatively, in some embodiments, the thickness of the base metal 30 may also be less than the sum of the thicknesses of the emitter step 21 and the emitter metal 22. The base metal 30 includes an end portion 411 and multiple finger portions 412. The multiple finger portions 412 extend in the second direction and are arranged at intervals in the first direction. One emitter step 21 and one emitter metal 22 are located between every two adjacent finger portions 412. That is, multiple sets of emitter steps 21 and emitter metals 22 are also arranged at intervals in the first direction, and a gap is formed between two adjacent sets of emitter steps 21 and emitter metals 22. The end portion 411 is connected to ends of the multiple finger portions 412 near the first side surface 1141. The base metal 30 extending at least partially beyond the edge of the first surface 12 may involve one or more of the multiple finger portions 412 extending beyond the edge of the first surface 12, or the end portion 411 extending beyond the edge of the first surface 12.

In this embodiment, at least a portion of the base metal 30 extends beyond the edge of the first surface 12, enabling a reduction in a size of the base step 11 while maintaining a same area of the base metal 30. For example, if the end portion 411 extends beyond the edge of the first surface 12 in the second direction, a size of the base step 11 in the second direction may be reduced. If a certain finger portion 412 extends beyond the edge of the first surface 12 in the first direction, a size of the base step 11 in the first direction may be reduced. Therefore, a junction area may be reduced to achieve higher high-frequency characteristics. Alternatively, if the size of the base step 11 remains unchanged, the width of the base metal 30 can be increased, reducing the resistance of the base metal 30 without enlarging the junction area, which also enhances high-frequency characteristics.

In some embodiments, the HBT also includes a dielectric layer 800, which is disposed on the second surface 13 and is arranged side by side with the base step 11. The dielectric layer 800 is disposed on an outer side of the first passivation layer 231 facing away from the semiconductor stack 10, and the base metal 30 extends at least partially onto the dielectric layer 800.

In some embodiments, the dielectric layer 800 is made of a dielectric material, which may be a low-dielectric-constant organic polymer material such as PI or PBO, and also has a higher thermal stability. A dielectric constant of the dielectric material filled in the dielectric layer 800 is 0 to 10 F/m. For example, the dielectric constant of the dielectric material filled in the dielectric layer 800 may be 2.5 F/m to 4.0 F/m, more specifically, for example, 2.5 F/m to 2.7 F/m or 3.0 F/m to 4.0 F/m. For example, a thermal decomposition temperature of the dielectric material filled in the dielectric layer 800 is greater than 300° C., and a thermal expansion coefficient of the dielectric material filled in the dielectric layer 800 is less than 100 PPM. In some embodiments, the dielectric layer 800 can also be a hollow cavity structure, and the dielectric material filled in the dielectric layer 800 may be air, that is, it can also be said that the dielectric layer 800 is filled with air.

The dielectric layer 800 being disposed on the second surface 13 and being arranged side by side with the base step 11 may indicates that the dielectric layer 800 is disposed on one side of the base step 11 or the dielectric layer 800 surrounds the base step 11 and is disposed outside the multiple step side surfaces 114 of the base step 11.

In some embodiments, the dielectric layer 800 has an outer surface 810 facing away from the base step 11, and a maximum spacing (D2) between the outer surface 810 and the base step 11 is less than or equal to 30 micrometers. Specifically, a range of D2 is 1 micrometer to 30 micrometers.

A portion of the first passivation layer 231 disposed between the dielectric layer 800 and the base step 11 includes a first portion of the first passivation layer 231 covering the step side surface 114 and a second portion of the first passivation layer 231 covering the second surface 13. It can also be stated that the dielectric layer 800 is adjacent to the base step 11 with the first passivation layer 231 interposed between them. Alternatively, it can be described that the base step 11 and the dielectric layer 800 protrude side by side from the second surface 13, with the base step 11 and the semiconductor stack 10 being separated by the first passivation layer 231.

In this embodiment, by arranging the dielectric layer 800 side by side with the base step 11, a spacing between the metal and the semiconductor material may be increased, thereby reducing the parasitic capacitance. When the dielectric layer 800 is filled with a dielectric material, the dielectric material in the dielectric layer 800 can also provide support for a portion of the base metal 30 extending beyond the edge of the first surface 12, ensuring the stability of the structure.

In some embodiments, the dielectric layer 800 is disposed outside at least one of the first side surface 1141, the fourth side surface 1144, and the first side surface 1141 of the base step 11. This allows a long side of the end portion 411 or at least one finger portion 412 to extend onto the dielectric layer 800, ensuring that the base metal 30 has more area extending outside the base step 11, achieving better effects of reducing the junction area or reducing the resistance of the base metal 30.

In a specific embodiment, referring to FIG. 18, the multiple finger portions 412 include a third finger portion 4121 and a fourth finger portion 4122 located at two opposite ends of the end portion 411 in the first direction. The dielectric layer 800 surrounds the first side surface 1141, the fourth side surface 1144, and the third side surface 1143, that is, the dielectric layer 800 includes a first portion located outside the first side surface 1141, a second portion located outside the fourth side surface 1144, and a third portion located outside the third side surface 1143. The end portion 411, the third finger portion 4121, and the fourth finger portion 4122 all extend over the dielectric layer 800. Specifically, the end portion 411 extends onto the third portion of the dielectric layer 800, the third finger portion 4121 extends onto the second portion of the dielectric layer 800, and the fourth finger portion 4122 extends onto the first portion of the dielectric layer 800. This can achieve the effect of reducing the size of the base step 11 from multiple directions and improving the frequency characteristics. In some embodiments, the multiple finger portions 412 further include a middle finger portion 4123 disposed between the third finger portion 4121 and the fourth finger portion 4122. In some embodiments, as shown in FIG. 22, there may be no middle finger portion 4123. In some embodiments, as shown in FIG. 28, the dielectric layer 800 may further include a fourth portion located outside the second side surface 1142. The second metal 51 may be led out along the outside of the fourth portion, which can also reduce the parasitic capacitance between the second metal 51 and the base step 11. Specifically, in some embodiments, the dielectric layer 800 includes an extension dielectric portion 820, which is located above the portion of the first passivation layer 231 covering the first surface 12. More specifically, the portion of the dielectric layer 800 located outside the first side surface 1141 extends to cover the portion of the first passivation layer 231 on the first surface 12 to form the extension dielectric portion 820. The base metal 30 includes a first extension portion 4111, which extends to the extension dielectric portion 820. The setting of the extension dielectric portion 820 can reduce a contact area between the base metal 30 and the base step 11 while the base metal 30 has a same width, reducing the junction capacitance. Moreover, a spacing between the first extension portion 4111 and the first surface 12 is increased, thereby reducing parasitic capacitance. In some embodiments, a thickness range of the extension dielectric portion 820 is 0.01 micrometers to 2 micrometers. Of course, in some other embodiments, a height of the dielectric layer 800 may be lower than a height of the base step 11, that is, a top of the dielectric layer 800 is lower than the first surface 12 (see FIGS. 26 and 28 for reference).

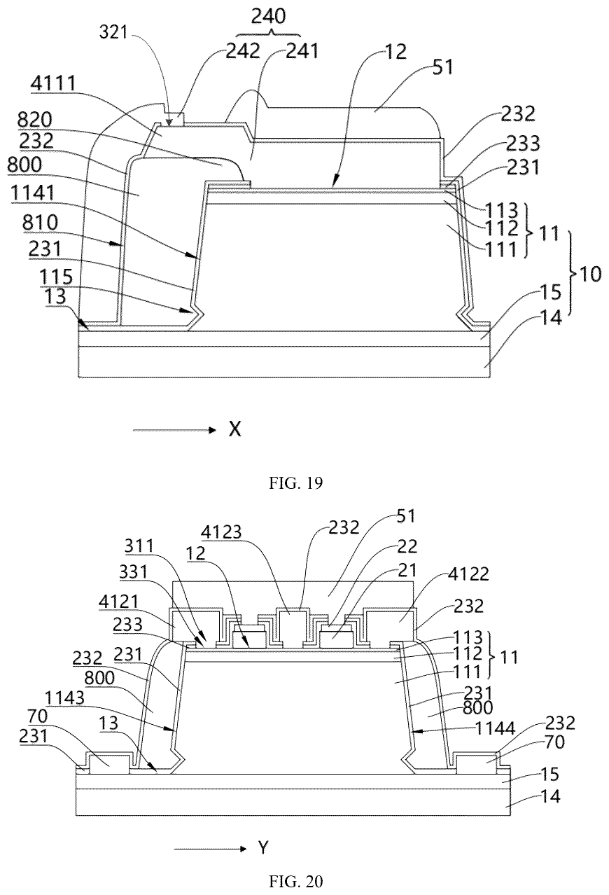

In some embodiments, as shown in FIGS. 19 and 20, the HBT also includes a second passivation layer 232, which covers the first passivation layer 231, the base metal 30, and the dielectric layer 800. The second passivation layer 232 may also cover the middle finger portion 4123 and fill the gap between two adjacent sets of emitter steps 21 and emitter metals 22. The second passivation layer 232 defines a sixth opening 321 located on the base metal 30. The first metal 240 also includes a connection metal 242. The connection metal 242 is located outside the second passivation layer 232 and is connected to the base metal 30 through the sixth opening 321. The first metal 240 extends at least partially beyond the outer surface 810 of the dielectric layer 800, that is, a portion of the base metal 30 covers the outer surface 810 of the dielectric layer 800 or a portion of the connection metal 242 is located outside the outer surface 810 of the dielectric layer 800.

A material of the second passivation layer 232 may be selected with reference to the material of the first passivation layer 231. A thickness of the second passivation layer 232 is 100 angstroms to 3000 angstroms. A portion of the second passivation layer 232 covers the base metal 30. For the first passivation layer 231, it has a first portion covering the base step 11 and exposed outside the dielectric layer 800, and a second portion covering the emitter step 21 and the emitter metal 22. A portion of the second passivation layer 232 covers a portion of the first passivation layer 231. A portion of the dielectric layer 800 is exposed outside the base metal 30. A portion of the second passivation layer 232 covers this portion of the dielectric layer 800 exposed outside the base metal 30.

Specifically, in some embodiments, as shown in FIG. 19, the base metal 30 includes a first extension portion 4111 located on the dielectric layer 800. The sixth opening 321 is located above the first extension portion 4111. The connection metal 242 is connected to the base metal 30 through the sixth opening 321. In some embodiments, the connection metal 242 extends along a portion of the second passivation layer 232 covering the outer surface 810 of the dielectric layer 800, which makes the connection metal 242 and the step side surface 114 be separated by the dielectric layer 800. A thickness of the dielectric layer 800 can increase a spacing between the connection metal 242 and the base step 11, thereby reducing the parasitic capacitance between the metal and the step side surface 114, and also improving the high-frequency characteristics of the HBT. Specifically, the first extension portion 4111 may be a portion of the end portion 411, or the first extension portion 4111 includes a portion of the end portion 411 and a portion of an end of at least one finger portion 412 connected to the end portion 411. The dielectric layer 800 located outside the first side surface 1141 is disposed between the connection metal 242 and the base step 11.

In some embodiments, as shown in FIG. 19, the sixth opening 321 is located above the first extension portion 4111 and outside the base step 11, which allows a portion of the connection metal 242 located below a top of the first extension portion 4111 to have no base step 11 underneath, thereby reducing the parasitic capacitance between the connection metal 242 and the base step 11.

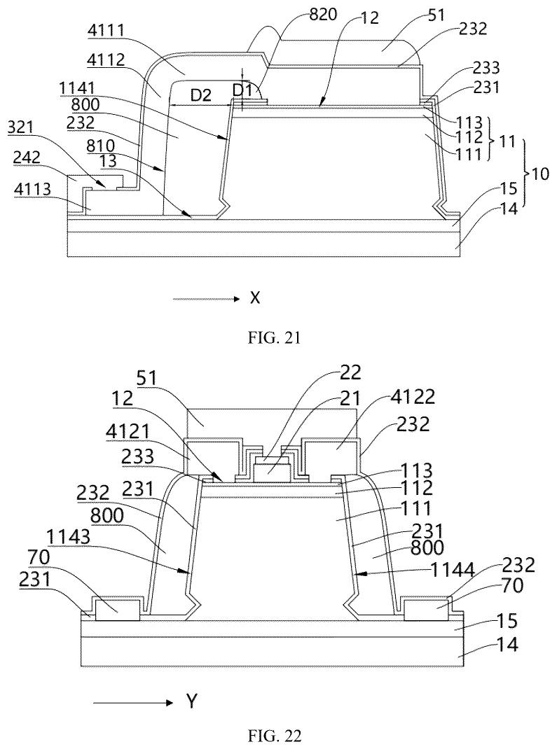

Referring to FIG. 21, in some other embodiments, the base metal 30 includes a first extension portion 4111, a second extension portion 4112, and a third extension portion 4113 connected in sequence. The first extension portion 4111 is located on the dielectric layer 800. The second extension portion 4112 covers the outer surface 810, and the third extension portion 4113 is located on the portion of the first passivation layer 231 covering the second surface 13. The sixth opening 321 is located above the third extension portion 4113. Specifically, the first extension portion 4111, the second extension portion 4112, and the third extension portion 4113 together form the end portion 411. Alternatively, the first extension portion 4111 further includes ends of the multiple finger portions 412 connected to the end portion 411. Through the above settings, the dielectric layer 800 is disposed between the second extension portion 4112 and the step side surface 114, which can increase a width of the base metal 30 to reduce resistance and improve high-frequency characteristics, and also reduce the parasitic capacitance between the second extension portion 4112 and the step side surface 114 to improve high-frequency characteristics.

In some embodiments, as shown in FIG. 16, a first edge 4114 of the end portion 411 near the multiple finger portions 412 is disposed above the dielectric layer 800 and outside the base step 11. That is, there is no base step 11 below the end portion 411, which allows the size of the base step 11 to be reduced while ensuring a sufficient width of the end portion 411, and also reduces the parasitic capacitance between the end portion 411 and the base step 11.

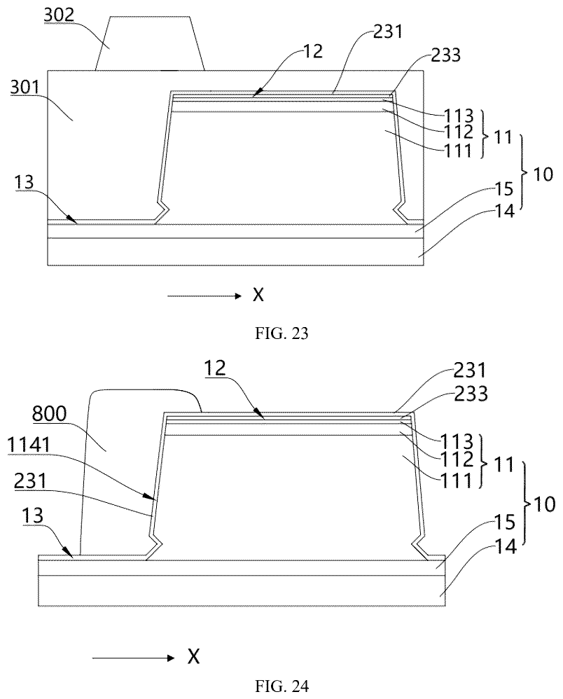

The manufacturing method of the HBT provided in the above embodiments of the present disclosure can refer to FIGS. 23 to 25.

As shown in FIG. 23, first, a dielectric material layer 301 is formed on the basic structure, and then the dielectric material layer 301 is etched using a first photoresist 302. The base structure includes a semiconductor stack 10, an emitter step 21 and an emitter metal 22 protruding from the first surface 12, as well as a third passivation layer 233 and a first passivation layer 231. A portion of the dielectric material layer 301 covering the second surface 13 from the first passivation layer 231 extends over a top of the basic structure in a direction gradually away from a substrate. On a cross section shown in FIG. 23, a portion of an orthographic projection of the first photoresist 302 on the second surface 13 coincides with the base step 11, and another portion of the orthographic projection is located outside the base step 11, so that a structure as shown in FIG. 24 is obtained after the etching is completed. The dielectric material layer 301 is etched to form a dielectric step, which includes a third portion located on a side of the first side surface 1141 and a first portion and a second portion located on opposite sides of the base step 11 in the first direction, forming a structure surrounding three sides of the base step 11. By setting a shape and a position of the first photoresist 302 during etching, the dielectric step is arranged side by side with the base step 11, and the third portion of the dielectric step on the first side surface 1141 can form an extension dielectric portion 820 located above the first surface 12. The dielectric material layer 301 may be a low-dielectric-constant organic polymer material such as PI or PBO. This type of material is difficult to use for defining small-size openings. In this embodiment, by using the first photoresist 302 to etch the dielectric material layer 301, the dielectric material layer 301 can adopt a large-area opening method, which can avoid the process difficulties of small-size openings, is convenient to implement, and can ensure product yield.

Next, corresponding positions of the first passivation layer 231 and the third passivation layer 233 can be opened to define the fifth opening 311 and the seventh opening 331, and metal materials are deposited to form a base metal 30 and a collector metal 70. The base metal 30 is connected to the semiconductor stack 10 and extends partially over the dielectric layer 800. The collector metal 70 is connected to the sub-collector 15, resulting in a structure shown in FIGS. 17 and 18. Then, the second passivation layer 232 is covered, so that the second passivation layer 232 covers the first passivation layer 231, the base metal 30, the collector metal 70, and the dielectric step. A sixth opening 321 is formed at a corresponding position on the second passivation layer 232, and a metal material is deposited to form a connection metal 242 to connect with the base metal 30, and openings are made at top parts of the second passivation layer 232, the first passivation layer 231 and the third passivation layer 233 through a second photoresist, and a metal material is deposited to form a second metal 51 to connect with the emitter metal 22. Structures shown in FIGS. 19 and 20 are obtained. After forming the second passivation layer 232, the dielectric material forming the dielectric step can be removed to obtain a hollow dielectric layer 800, or a space occupied by the dielectric step is the dielectric layer 800 without removing the dielectric material of the dielectric step.

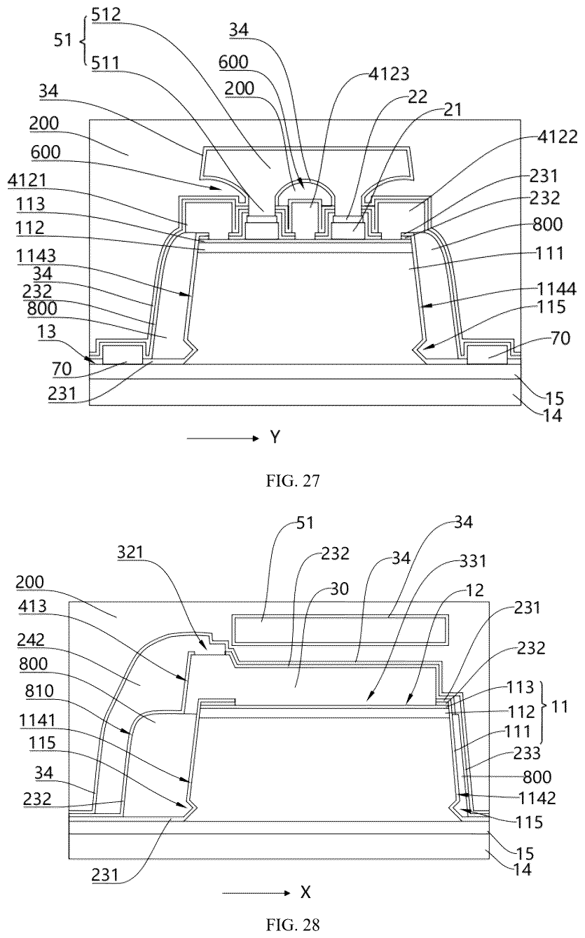

In some embodiments, before forming the second metal 51, the second photoresist is not removed. Instead, a third photoresist is formed directly on top of the second photoresist, and then the second metal 51 is formed. As shown in FIGS. 26 to 28, a portion of the second metal 51 located within an opening of the second photoresist forms a second connection portion 511, and a portion of the second metal 51 located above the second photoresist and within an opening of the third photoresist forms an extension portion 512. The extension portion 512 extends above the finger portion 412 in the first direction. In this embodiment, the second photoresist is not removed before forming the second metal 51, which can use the second photoresist as a support for the extension portion 512, as such, this method uses fewer photoresists and simplifies the process flow.

After the second metal 51 is formed, the second photoresist 303 and the third photoresist 304 are removed. A gap 600 is formed between the extension portion 512 and the first passivation layer 231 covering the finger portion 412. The connection metal 242 may be formed after the second metal 51 is formed. Finally, a fourth passivation layer 34 and a first dielectric structure 200 are prepared, so that the fourth passivation layer 34 covers surfaces of the second passivation layer 232, the second metal 51, and the connection metal 242. The first dielectric structure 200 covers the fourth passivation layer 34, and a portion of the first dielectric structure 200 covering the second surface 13 from the fourth passivation layer 34 extends in a direction gradually away from the substrate 14 to a top of the fourth passivation layer 34 covering the second metal 51. The first dielectric structure 200 can fill the gap 600, reducing the parasitic capacitance between the second metal 51 and the base metal 30 located below the second metal 51. At the same time, the first dielectric structure 200 can also provide support for the extension portion 512, ensuring the stability of the structure. In a subsequent process, the first dielectric structure 200 and the portion of the fourth passivation layer 34 covering the second metal 51 may be opened to realize the connection between the second metal 51 and the external structure.

In some embodiments, a thickness of the fourth passivation layer 34 is in a range of 0.01 micrometers to 0.3 micrometers.

In some embodiments, a height of the gap 600 is in a range of 0.2 micrometers to 1 micrometer. The height of the gap 600 is a maximum spacing between a surface of the extension portion 512 facing towards the base metal 30 and a portion of the first passivation layer 231 covering the finger portion 412, also known as the suspension height. Choosing an appropriate height for the gap 600 can ensure a better effect of reducing parasitic capacitance while ensuring the structural stability of the second metal 51.

In some embodiments, a thickness of the extension portion 512 is less than a thickness of the second connection portion 511, which can ensure the stability of the second metal 51 and prevent the second metal 51 from being damaged during the manufacturing process. By setting the thickness of the extension portion 512 and the thickness of the second connection portion 511 within appropriate ranges, an arch-shaped portion of the extension portion 512 located above the middle finger portion 4123, as shown in FIG. 26, may be prevented from breaking.

In some embodiments, a spacing between an edge of the extension portion 512 and an edge of the second connection portion 511 on a same side as the edge of the extension portion 512 in the first direction is 0.1 micrometers to 5 micrometers. For example, a spacing between an edge of the extension portion 512 near the fourth side surface 1144 and an edge of the second connection portion 511 near the fourth side surface 1144 in the first direction is in a range of 0.1 micrometers to 5 micrometers.

In some embodiments, along the first direction, the spacing between the edge of the extension portion 512 and the edge of the second connection portion 511 on the same side as the edge of the extension portion 512 is less than or equal to 5 times the thickness of the extension portion 512, and in some embodiments less than 2 times. This can prevent the extension portion 512 from breaking due to an overly long suspension portion of the extension portion 512 above the finger portion 412.

In some embodiments, a width of the second connection portion 511 in the first direction gradually increases in a direction facing away from the emitter metal 22. That is, a side surface of the second connection portion 511 is inclined. In some embodiments, the second connection portion 511 and a bottom surface of the extension portion 512 may be transitioned with an arc surface. In some embodiments, an inclination angle of a side surface of the second connection portion 511 is in a range of 0 to 45°. The inclination angle of the side surface of the second connection portion 511 is an angle between the second connection portion 511 and a vertical direction. The inclined side surface of the second connection portion 511 can increase an connection area between the second connection portion 511 and the extension portion 512, enhancing the overall structural stability of the second metal 51, and can also ensure a smaller contact area between the second connection portion 511 and the emitter metal 22.

In some embodiments, the second metal 51 includes a drainage portion communicating with the gap 600. In an orthogonal projection of the second metal 51 on the first surface 12 (i.e., a top view of the second metal 51), the drainage portion extends in the first direction. The drainage portion may be a through hole extending from bottom to top (along a stacking direction of the emitter step 21 and the emitter metal 22). In some embodiments, the drainage portion may be notch-shaped with an opening at an end of the drainage portion along the first direction. By setting the drainage portion, a material of the first dielectric structure 200 may better fill the gap 600 during the subsequent process of forming the first dielectric structure 200.

A number of the drainage portion may be one or more. When the number of drainage portion is multiple, the multiple drainage portions are arranged at intervals along the second direction. In some embodiments, when the drainage portions are notch-shaped, openings of adjacent drainage portions along the second direction face opposite directions, which ensures the overall structural stability of the second metal layer 51.

Some embodiments of the present disclosure further provide an RF module, which includes the HBT described in any of the above embodiments or the HBT obtained by the manufacturing method described in the above embodiments. The RF module, for example, integrates an RF switch and a filter. The RF module provided in this embodiment at least has the same effects as the HBT 100, and will not be repeated herein.

Some embodiments of the present disclosure further provide a communication device, which includes the above RF module. The communication device may be, for example, a mobile phone or a WIFI wireless router device. The communication device at least has the same effects as the above HBT 100, and will not be repeated herein.

What is claimed is:

1. A heterojunction bipolar transistor (HBT), comprising:
a semiconductor stack having a first surface and a second surface, wherein the semiconductor stack comprises: an emitter step protruding from the first surface, and a base step disposed on the second surface; the first surface is a surface of the base step facing away from the second surface; and the base step comprises a step side surface connecting the first surface and the second surface;
an emitter metal, disposed on the emitter step;
a first passivation layer, wherein the first passivation layer covers at least a side surface of the emitter metal and extends to cover a portion of the first surface exposed outside the emitter step, the step side surface, and a portion of the first surface exposed outside the base step;
a first metal, wherein the first metal comprises a base metal, the base metal is at least partially disposed on the first surface, and the base metal is adjacent to the emitter step and is spaced apart from the emitter step; and
a dielectric layer, wherein the dielectric layer is disposed on the second surface and arranged side by side with the base step, and the dielectric layer is disposed on an outer side of the first passivation layer facing away from the semiconductor stack.

2. The HBT as claimed in claim 1, further comprising:
multiple emitter structures, disposed on the emitter step and spaced apart from each other, wherein a gap is defined between every two adjacent emitter structures of the multiple emitter structures; the base metal further comprises a first finger portion, the first finger portion is disposed in the gap and in contact connection with the semiconductor stack;
an isolation structure, wherein the isolation structure comprises a first isolation structure; the first isolation structure fills the gap and covers the first finger portion; and the isolation structure is made of an insulating material; and
an emitter connection metal, disposed on sides of the multiple emitter structures and the first isolation structure facing away from the semiconductor stack, wherein the emitter connection metal is in contact connection with the multiple emitter structures.

3. The HBT as claimed in claim 2, wherein the first passivation layer comprises a first portion, the first portion of the first passivation layer covers a surface of the first finger portion facing away from the semiconductor stack and covers side surfaces of every two adjacent emitter structures facing towards the gap; and
wherein the HBT further comprises a first dielectric layer, the first dielectric layer is disposed on a side of the first portion facing away from the semiconductor stack, the first portion and the first dielectric layer together form the first isolation structure, and a material of the first portion is different from that of the first dielectric layer.

4. The HBT as claimed in claim 3, wherein a thickness of the first dielectric layer is greater than or equal to 1000 angstroms, and a dielectric constant of the first dielectric layer is lower than that of the first portion of the first passivation layer.

5. The HBT as claimed in claim 2, wherein each emitter structure of the multiple emitter structures comprises the emitter step and the emitter metal sequentially stacked on the semiconductor stack in that order, and a spacing between a surface of the emitter metal facing away from the semiconductor stack and a surface of the base metal facing away from the semiconductor stack is greater than or equal to 3000 angstroms.

6. The HBT as claimed in claim 3, wherein the semiconductor stack has a semiconductor slope adjacent to the first surface, the base metal further comprises a first connection portion disposed on the first surface, and the first connection portion is connected to the first finger portion;
wherein the first passivation layer further comprises a second portion, the second portion covers the semiconductor slope, and the dielectric layer covers the second portion of the first passivation layer;
wherein the isolation structure further comprises a second isolation structure, the dielectric layer and the second portion of the first passivation layer together form the second isolation structure; and
wherein the HBT further comprises a base connection metal, and the base connection metal is connected to the base metal and extends to a side of the dielectric layer facing away from the second portion of the first passivation layer.

7. The HBT as claimed in claim 2, wherein the first passivation layer covers the semiconductor stack and the multiple emitter structures, the first passivation layer defines a contact opening, the multiple emitter structures are disposed with intervals in a first direction, surfaces of the multiple emitter structures facing away from the semiconductor stack are connected to the emitter connection metal through the contact opening, and a spacing between outermost two opposite edges of the multiple emitter structures in the first direction being less than a width of the contact opening in the first direction.

8. The HBT as claimed in claim 7, wherein a thickness of the dielectric layer is greater than or equal to 5000 angstroms.

9. The HBT as claimed in claim 1, wherein the first passivation layer defines an opening disposed on the first surface, the base metal is connected to the semiconductor stack through the opening, the base metal extends at least partially beyond an edge of the first surface, and the base metal extends at least partially onto the dielectric layer.

10. The HBT as claimed in claim 1, wherein a dielectric constant of a dielectric material of the dielectric layer is lower than that of the first passivation layer.

11. The HBT as claimed in claim 10, wherein the step side surface comprises a third side surface and a fourth side surface facing towards each other in the first direction, and a first side surface and a second side surface facing towards each other in a second direction and connected between the third side surface and the fourth side surface;
wherein the base metal comprises an end portion and multiple finger portions, the multiple finger portions extend in the second direction and are arranged at intervals in the first direction, the emitter step and the emitter metal are disposed between two adjacent finger portions of the multiple finger portions, and the end portion is connected to ends of the multiple finger portions near the first side surface; and
wherein the dielectric layer is disposed outside at least one of the third side surface, the fourth side surface and the first side surface of the step side surface.

12. The HBT as claimed in claim 11, wherein the multiple finger portions comprise a third finger portion and a fourth finger portion disposed on two ends of the end portion in the first direction; the dielectric layer is disposed around the third side surface, the fourth side surface and the first side surface; and the end portion, the third finger portion and the fourth finger portion extend onto the dielectric layer.

13. The HBT as claimed in claim 10, wherein the dielectric layer comprises an extension dielectric portion, and the extension dielectric portion is disposed on a portion of the first passivation layer covering the first surface.

14. The HBT as claimed in claim 10, further comprising a second passivation layer, wherein the second passivation layer covers the first passivation layer, the base metal, and the dielectric layer; the second passivation layer defines an opening disposed on the base metal; the first metal further comprises a connection metal; and the connection metal is disposed outside the second passivation layer and is connected to the base metal through the opening; and
wherein the dielectric layer has an outer surface facing away from the base step, and the first metal extends at least partially beyond the outer surface.

15. The HBT as claimed in claim 14, wherein the base metal comprises a first extension portion, the first extension portion extends onto the dielectric layer, the opening is defined on the first extension portion, and the connection metal extends along a portion of the second passivation layer covering the outer surface.

16. The HBT as claimed in claim 14, wherein the base metal comprises a first extension portion, a second extension portion and a third extension portion sequentially connected in that order, the first extension portion is disposed on the dielectric layer, the second extension portion covers the outer surface, the third extension portion is disposed on a portion of the first passivation layer covering the second surface, and the opening is disposed on the third extension portion.

17. The HBT as claimed in claim 11, wherein a first edge of the end portion near the multiple finger portions is disposed above the dielectric layer and outside the base step.

18. The HBT as claimed in claim 9, wherein the dielectric layer has an outer surface facing away from the base step, and a maximum spacing between the outer surface and the base step is less than or equal to 30 micrometers.

19. A radio frequency (RF) module, comprising the HBT as claimed in claim 1.

20. A communication device, comprising the RF module as claimed in claim 19.
